(19) United States
(12) Patent Application Publication
(10) Pub. No.: US 2020/0192219 A1
(43) Pub. Date: Jun. 18, 2020

(54) IMPRINT APPARATUS, INFORMATION PROCESSING APPARATUS, AND METHOD OF MANUFACTURING ARTICLE

(71) Applicant: CANON KABUSHIKI KAISHA, Tokyo (JP)

(72) Inventors: Shinichi Hirano, Utsunomiya-shi (JP); Masayoshi Fujimoto, Utsunomiya-shi (JP)

(21) Appl. No.: 16/701,249

(22) Filed: Dec. 3, 2019

(30) Foreign Application Priority Data
Dec. 14, 2018 (JP) 2018-234712

(51) Int. Cl. G03F 7/00

(52) U.S. Cl. CPC G03F 7/0002

(57) ABSTRACT

The present invention provides an imprint apparatus that forms a pattern of an imprint material on a substrate using a mold, including a processing unit configured to perform processing of locally irradiating the imprint material on the substrate with light in accordance with an irradiation condition to locally increase a viscosity of the imprint material, and a control unit configured to provide a user interface in which a first image including information included in the irradiation condition and indicating an irradiation region to be irradiated with light in a region on the substrate and a second image indicating at least one of a supply position to which the imprint material is to be supplied on the substrate and a shape of the pattern region of the mold are superimposed with each other and displayed.

### BACKGROUND OF THE INVENTION

### Field of the Invention

The present invention relates to an imprint apparatus, an information processing apparatus, and a method of manufacturing an article.

### Description of the Related Art

An imprint apparatus supplies an imprint material on a substrate and cures the imprint material in a state in which a mold is in contact with the imprint material on the substrate, thereby forming a pattern made of a cured product of the imprint material on the substrate. The imprint material is supplied onto the substrate by discharging the imprint material from a dispenser in accordance with a drop recipe or the data converted from the drop recipe. A drop recipe is also called a drop pattern, and is information indicating the arrangement (supply positions) of the imprint material on the substrate.

Each of Japanese Patent Laid-Open Nos. 2011-521438, 2013-69919 and 2013-69918 proposes a technique called frame exposure used in an imprint apparatus to prevent an imprint material from oozing out to the outside (outer peripheral portion) of a shot region on a substrate when bringing a mold into contact with the imprint material on the substrate. Frame exposure is a technique of performing light irradiation in a frame shape with respect to the outer peripheral portion of a shot region on a substrate upon bringing a mold into contact with an imprint material on the substrate, thereby curing or evaporating the imprint material that otherwise oozes to the outer peripheral portion of the shot region. In frame exposure, light irradiation is performed in a frame shape with respect to the outer peripheral portion of a shot region on a substrate in according with irradiation conditions (frame exposure recipe).

However, setting (generating) a drop recipe and frame exposure irradiation conditions puts a heavy burden on a user. In particular, it requires a long time to set a drop recipe and frame exposure irradiation conditions so as to reduce the unfitting of an imprint material to the pattern of a mold and suppress the oozing out of the imprint material onto the outer peripheral portion of a shot region. Therefore, in an imprint apparatus, there is demanded a technique that supports setting of a drop recipe and frame exposure irradiation conditions, that is, a technique that enables easy setting of a drop recipe and frame exposure irradiation conditions, thereby improving usability.

### SUMMARY OF THE INVENTION

The preset invention provides an imprint apparatus advantageous in improving usability in setting imprint processing.

According to one aspect of the present invention, there is provided an imprint apparatus that performs imprint processing to form a pattern of an imprint material on a substrate using a mold, including a processing unit configured to, before the imprint material is cured by irradiating the entire imprint material with light in a state in which the imprint material and a pattern region of the mold are in contact with each other, perform processing of locally irradiating the imprint material on the substrate with light in accordance with an irradiation condition to locally increase a viscosity of the imprint material, and a control unit configured to provide a user interface in which a first image including information included in the irradiation condition and indicating an irradiation region to be irradiated with light in a region on the substrate and a second image indicating at least one of a supply position to which the imprint material is to be supplied on the substrate and a shape of the pattern region of the mold are superimposed with each other and displayed.

Further features of the present invention will become apparent from the following description of exemplary embodiments with reference to the attached drawings.

### BRIEF DESCRIPTION OF THE DRAWINGS

FIG. 1 is a schematic view showing the arrangement of an imprint apparatus as one aspect of the present invention.

FIG. 2 is a view for explaining an example of processing blocks in a control unit.

FIG. 3 is a view showing an example of a screen provided as a user interface.

FIG. 4 is a view showing another example of the screen provided as the user interface.

FIG. 5 is a view showing still another example of the screen provided as the user interface.

FIG. 6 is a view showing still another example of the screen provided as the user interface.

FIG. 7 is a view showing an example of another screen provided as the user interface.

FIG. 8 is a view showing still another example of the screen provided as the user interface.

FIG. 9 is a view showing still another example of the screen provided as the user interface.

FIG. 10 is a view showing still another example of the screen provided as the user interface.

FIG. 11 is a view showing still another example of the screen provided as the user interface.

FIG. 12 is a view showing still another example of the screen provided as the user interface.

FIG. 13 is a view showing still another example of the screen provided as the user interface.

FIG. 14 is a view showing still another example of the screen provided as the user interface.

FIG. 15 is a view showing still another example of the screen provided as the user interface.

FIG. 16 is a view showing still another example of the screen provided as the user interface.

FIG. 17 is a view showing still another example of the screen provided as the user interface.

FIG. 18 is a view showing still another example of the screen provided as the user interface.

FIG. 19 is a view showing still another example of the screen provided as the user interface.

FIG. 20 is a view showing changes in exposure dose of light irradiation in frame exposure.

FIG. 21 is a view showing an example of still another screen provided as the user interface.

FIG. 22 is a view showing an example of a system including an information processing apparatus as one aspect of the present invention, the imprint apparatus, and a supervising control apparatus.

FIG. 23 is a view for explaining an example of processing blocks in a control unit of the information processing apparatus shown in FIG. 22.

FIGS. 24A to 24F are views for explaining a method of manufacturing an article.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

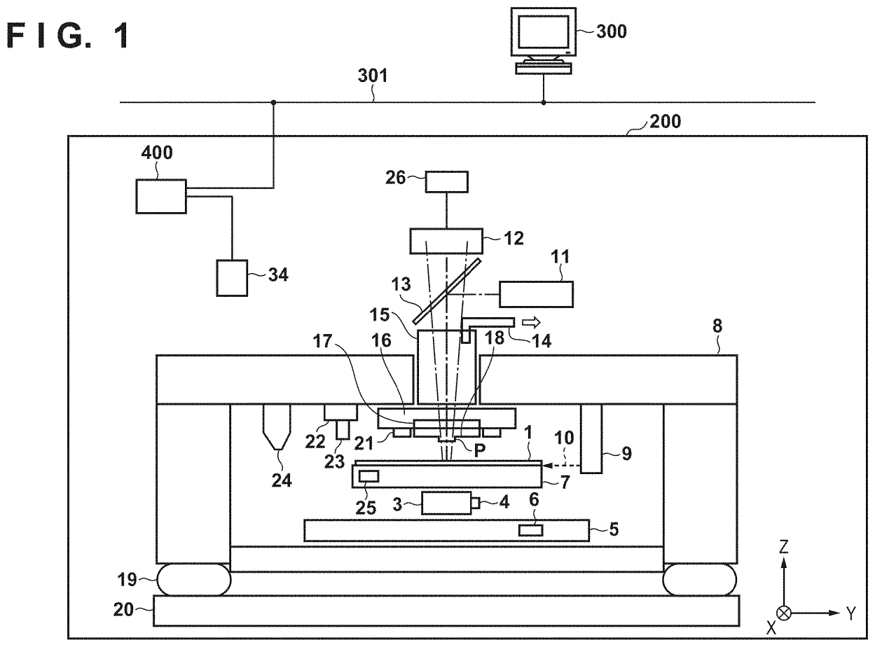

FIG. 1 is a schematic view showing the arrangement of an imprint apparatus 200 as one aspect of the present invention. The imprint apparatus 200 is a lithography apparatus that is adopted in a lithography step as a manufacturing step of a semiconductor device or a liquid crystal display device to form a pattern on a substrate. In this embodiment, the imprint apparatus 200 brings an imprint material supplied onto a substrate into contact with a mold and applies curing energy to the imprint material, thereby forming a pattern of the cured product to which an uneven pattern of the mold is transferred.

As the imprint material, a curable composition (to be also referred to as a resin in an uncured state) to be cured by receiving curing energy is used. Examples of the curing energy are an electromagnetic wave and the like. As the electromagnetic wave, for example, light selected from the wavelength range of 10 nm (inclusive) to 1 mm (inclusive) is used. Examples of the electromagnetic wave are infrared light, a visible light beam, and ultraviolet light.

The curable composition is a composition cured with light irradiation. The photo-curable composition cured by light irradiation contains at least a polymerizable compound and a photopolymerization initiator, and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used. A member made of a material different from that of the substrate may be formed on the surface of the substrate. More specifically, examples of the substrate include a silicon wafer, a semiconductor compound wafer, silica glass, and the like.

As shown in FIG. 1, the imprint apparatus 200 includes a chamber for preventing the entry of a foreign substance and maintaining a constant temperature and humidity in an imprint environment in which the imprint apparatus 200 is installed. The imprint apparatus 200 includes a first measurement unit 4, a second measurement unit 6, a substrate stage 7, a bridge structure 8, a third measurement unit 9, a light source unit 11, an alignment measurement unit 12, a half mirror 13, an exhaust duct 14, a connecting member 15, and a mold head 16. The imprint apparatus 200 further includes an air spring 19, a base 20, a gas supply unit 21, a holder 22, an imprint material supply unit 23, an off-axis scope 24, a pressure sensor 25, a detection unit 26, a control unit 400, and a user interface 34. Note that in this embodiment, directions are shown using the XYZ coordinate system in which the directions parallel to the surface of a substrate 1 are assumed to be on the X-Y plane. The directions parallel to the X-axis, the Y-axis, and the Z-axis in the XYZ coordinate system are assumed to be the X direction, the Y direction, and the Z direction, respectively.

The control unit 400 is connected to a supervising control apparatus 300 via a network 301. The mold head 16 includes a mold chuck 17 for holding a mold 18 including a pattern region (pattern surface) P. A pattern (unevenness) corresponding to a pattern to be formed on the substrate 1 is formed in the pattern region P of the mold 18.

The detection unit 26 detects, for example, as image information, the contact state between the imprint material on the substrate and the mold 18, the filling state of the imprint material on the substrate to the mold 18, and the separation state of the mold 18 from the cured imprint material on the substrate. In addition, the detection unit 26 can detect the positional relationship between the peripheral portion of the substrate 1 and a substrate chuck by moving the substrate stage 7.

The mold chuck 17 holds the mold 18 by, for example, vacuum suction. The mold chuck 17 may have a structure for preventing drop of the mold 18 from the mold chuck 17. In this embodiment, the mold chuck 17 is firmly coupled to the mold head 16.

The mold head 16 includes a mechanism for allowing the movement in three axis directions, that is, at least the Z-axis direction, a wX direction (the rotation direction around the X-axis), and a wY direction (the rotation direction around the Y-axis) with reference to the bridge structure 8. The mold head 16 is connected to the bridge structure 8 via the connecting member 15 and supported by the bridge structure 8. The alignment measurement unit 12 is also supported by the bridge structure 8.

The alignment measurement unit 12 is used for alignment between the mold 18 and the substrate 1. In this embodiment, the alignment measurement unit 12 includes an alignment detection system for detecting a mark formed on the mold 18 and a mark formed on the substrate stage 7 or the substrate 1 and generating an alignment signal. The alignment measurement unit 12 may include a camera and may have a function of observing the cured state of the imprint material on the substrate. In this case, the alignment measurement unit 12 can also observe the contact state between the imprint material on the substrate and the mold 18, the filling state of the imprint material on the substrate to the mold 18, and the separation state of the mold 18 from the cured imprint material on the substrate.

The half mirror 13 is arranged above the connecting member 15. Light from the light source unit 11 is reflected by the half mirror 13 and passes through the mold 18, and the imprint material on the substrate is irradiated with this light. The imprint material on the substrate is cured by irradiation of the light from the light source unit 11. The light source unit 11 includes a DMD (Digital Micro-mirror Device), and can perform light irradiation on the entire shot region of the substrate 1 or a partial region of the shot region of the substrate 1. In other words, the light source unit 11 can select a region to be irradiated with light in the shot region of the substrate 1 by the DMD.

The bridge structure 8 is supported by the base 20 via the air spring 19 for insulating the vibration from a floor. The air spring 19 has a structure generally employed in an exposure apparatus as an active anti-vibration function. The air spring 19 includes, for example, an XYZ relative position measurement sensor, an XYZ driving linear motor, a servo valve for controlling the internal air capacity of the air spring, and the like arranged in each of the bridge structure 8 and the base 20.

The imprint material supply unit 23 (dispenser) is attached to the bridge structure 8 via the holder 22. The imprint material supply unit 23 includes, for example, nozzles for supplying (discharging) the imprint material onto the substrate and a supply control unit for controlling the supply timing and supply amount of the imprint material. The imprint material supply unit 23 supplies, for example, the droplets of the imprint material onto the substrate. By moving the substrate stage 7 (that is, the substrate 1) while supplying the imprint material from the imprint material supply unit 23 onto the substrate, a region having an arbitrary shape (for example, a rectangular shape) on the substrate can be supplied with the imprint material.

In the imprint material supply unit 23, when the arrangement interval of the nozzles (discharge ports for discharging the imprint material) is made narrow, the time required for filling the pattern of the mold 18 with the imprint material can be shortened. However, if the arrangement interval of the nozzles is too narrow, the manufacture thereof becomes difficult, and droplets of the imprint material discharged from the adjacent nozzles can interfere with each other on the substrate. If the droplets of the imprint material interfere with each other, the droplets are connected to each other so that the supply positions of the imprint material (droplets) on the substrate are shifted. Therefore, in this embodiment, the arrangement interval of the nozzles is set such that the droplets of the imprint material discharged from the adjacent nozzles do not interfere with each other on the substrate.

The substrate 1 has a circular shape in this embodiment, and a plurality of chips can be formed in one shot region having a size of 33 mm×26 mm on the substrate. Note that the shot region on the substrate is not limited to 33 mm×26 mm, and may be larger than 33 mm×26 mm or smaller than 33 mm×26 mm. Examples of the shape of the shot region include a rectangular shape (rectangle), a jigsaw shape, and the like. When the shape of the shot region is a jigsaw shape, a measurement mark may be arranged in the jigsaw region. Note that in this embodiment, a shot region is a region having a size corresponding to the pattern region P of the mold 18, that is, a region (imprint region) in which a pattern of the imprint material corresponding to the pattern of the mold 18 is formed by one imprint processing operation.

When the uneven pattern of the imprint material is formed on the substrate using the imprint apparatus 200, a layer called a residual layer is left in a concave portion of the pattern. The residual layer must be removed by etching. The residual layer thickness is called an RLT (Residual Layer Thickness). If a residual layer having a thickness corresponding to the RLT necessary for etching is not formed, the substrate 1 is recessed by etching. In this embodiment, by combining the supply (discharge) of the imprint material by the imprint material supply unit 23 and the movement of the substrate stage 7, the imprint material is supplied to appropriate positions on the substrate, that is, supply positions to which the imprint material is to be supplied on the substrate.

The substrate stage 7 includes a substrate chuck for holding the substrate 1. The substrate stage 7 includes a mechanism for allowing the movement in six axis directions of X, Y, Z, ωX, ωY, and ωZ (the rotation direction around the Z-axis). In this embodiment, the substrate stage 7 is supported by the bridge structure 8 via an X slider 3 including an X-direction moving mechanism and a Y slider 5 including a Y-direction moving mechanism.

The first measurement unit 4 for measuring the relative position between the X slider 3 and the Y slider 5 is arranged in the X slider 3. The second measurement unit 6 for measuring the relative position between the Y slider 5 and the bridge structure 8 is arranged in the Y slider 5. Accordingly, the first measurement unit 4 and the second measurement unit 6 measure the position of the substrate stage 7 with reference to the bridge structure 8. In this embodiment, each of the first measurement unit 4 and the second measurement unit 6 includes an encoder (linear encoder).

The Z-direction distance between the substrate stage 7 and the bridge structure 8 is determined by the bridge structure 8, the X slider 3, and the Y slider 5. By maintaining the rigidity of the Z direction and the tilt direction of each of the X slider 3 and the Y slider 5 as high as about ten nm/N, the Z-direction variation of the imprint processing (operation) between the substrate stage 7 and the bridge structure 8 can be suppressed to the variation of about several ten nm.

The third measurement unit 9 is provided on the bridge structure 8. In this embodiment, the third measurement unit 9 includes an interferometer. The third measurement unit 9 emits measurement light 10 toward the end face of the substrate stage 7 and detects the measurement light 10 reflected by a mirror arranged at the end face of the substrate stage 7, thereby measuring the position of the substrate stage 7. The third measurement unit 9 measures the position of the substrate stage 7 at a position nearer than the first measurement unit 4 and the second measurement unit 6 with respect to the substrate 1 holding surface of the substrate stage 7. Note that in FIG. 1 although only one measurement light 10 emitted from the third measurement unit 9 to the end face of the substrate stage 7 is illustrated, the third measurement unit 9 is arranged so as to be able to measure at least the XY positions, the rotation amount, and the tilt amount of the substrate stage 7.

In order to improve the filling property of the imprint material to the pattern of the mold 18, the gas supply unit 21 supplies a filling gas to a portion near the mold 18, and more specifically a space between the mold 18 and the substrate 1. The filling gas includes at least one of permeable gas and condensable gas in order to quickly reduce the filling gas (bubbles) inserted between the mold 18 and the imprint material on the substrate and accelerate filling of the imprint material to the pattern of the mold 18. In this case, the permeable gas is a gas which has high permeability with respect to the mold 18 and is permeated through the mold 18 when bringing the mold 18 into contact with the imprint material on the substrate. The condensable gas is a gas which is liquefied (that is, condensed) when bringing the mold 18 into contact with the imprint material on the substrate.

The off-axis scope 24 detects the reference mark and the alignment mark formed on the reference plate arranged on the substrate stage 7 without being through the mold 18. The off-axis scope 24 can also detect the alignment mark formed on the substrate 1 (each shot region of the substrate 1). The off-axis scope 24 can further measure the height of each region on the substrate.

The pressure sensor 25 is arranged on the substrate stage 7 in this embodiment, and detects a pressure acting on the substrate stage 7 when bringing the mold 18 into contact with the imprint material on the substrate. The pressure sensor 25 functions as a sensor for detecting the contact state between the mold 18 and the imprint material on the substrate by detecting a pressure acting on the substrate stage 7. The pressure sensor 25 may be arranged on the mold head 16. In other words, the pressure sensor 25 only needs to be arranged on at least one of the mold head 16 and the substrate stage 7.

The control unit 400 is formed by a computer including a CPU, a memory, and the like, and comprehensively controls the respective units of the imprint apparatus 200 in accordance with the programs stored in a storage unit to operate the imprint apparatus 200. The control unit 400 controls imprint processing and processing associated with the imprint processing. In addition, the control unit 400 controls processing of generating a drop recipe. Here, a drop recipe includes information indicating the supply positions (arrangement of droplets of the imprint material) to which the imprint material is to be supplied on the substrate. The drop recipe further includes information regarding the supply amount of the imprint material to be supplied onto the substrate.

The refractive index of the filling gas supplied from the gas supply unit 21 is largely different from the refractive index of air. Accordingly, when the first measurement unit 4 and the second measurement unit 6 are exposed to the filling gas (that is, when the filling gas leaks to the measurement optical path of each of the first measurement unit 4 and the second measurement unit 6), the measurement values (measurement results) of the first measurement unit 4 and the second measurement unit 6 vary. This problem is conspicuous particularly for an interferometer having a long measurement optical path length. Since a high gain is obtained when controlling the position of the substrate stage 7, a servo error occurs. The influence on even an encoder having a short measurement optical path length cannot be neglected in an imprint apparatus in which the measurement accuracy on the order of nanometer is required. Note that since the measurement optical path length of the encoder is shorter than the measurement optical path length of the interferometer, the influence on the encoder is lighter than that on the interferometer. As shown in FIG. 1, in this embodiment, a distance to each of the first measurement unit 4 and the second measurement unit 6 from the gas supply unit 21 (the supply port of the filling gas of the gas supply unit 21) is sufficiently ensured, and each of the first measurement unit 4 and the second measurement unit 6 is formed from the encoder. Therefore, since each of the first measurement unit 4 and the second measurement unit 6 is arranged such that an influence of a variation in a measurement value by the filling gas is hardly affected, a servo error can hardly occur.

As described above, the gas supply unit 21 supplies the filling gas to the space between the mold 18 and the substrate 1 while the imprint processing is being performed. The filling gas supplied between the mold 18 and the substrate 1 is sucked from the upper portion of the mold head 16 via the exhaust duct 14 and exhausted outside the imprint apparatus 200. Note that the filling gas supplied between the mold 18 and the substrate 1 may not be exhausted outside the imprint apparatus 200, but may be recovered by a gas recovery mechanism (not shown).

Here, imprint processing in the imprint apparatus 200 is described. An imprint material is supplied from the imprint material supply unit 23 to a shot region on a substrate. Then, the mold head 16 is lowered to bring the imprint material on the substrate into contact with the pattern region P of the mold 18. In a state in which the imprint material on the substrate is in contact with the pattern region P of the mold 18, the imprint material on the substrate (on the shot region) is irradiated with light from the light source unit 11. Thus, the imprint material on the substrate is cured.

Then, the mold head 16 is lifted to separate (release) the mold 18 from the cured imprint material on the substrate. Thus, a pattern of the imprint material corresponding to the pattern of the pattern region P of the mold 18 is formed in the shot region of the substrate 1.

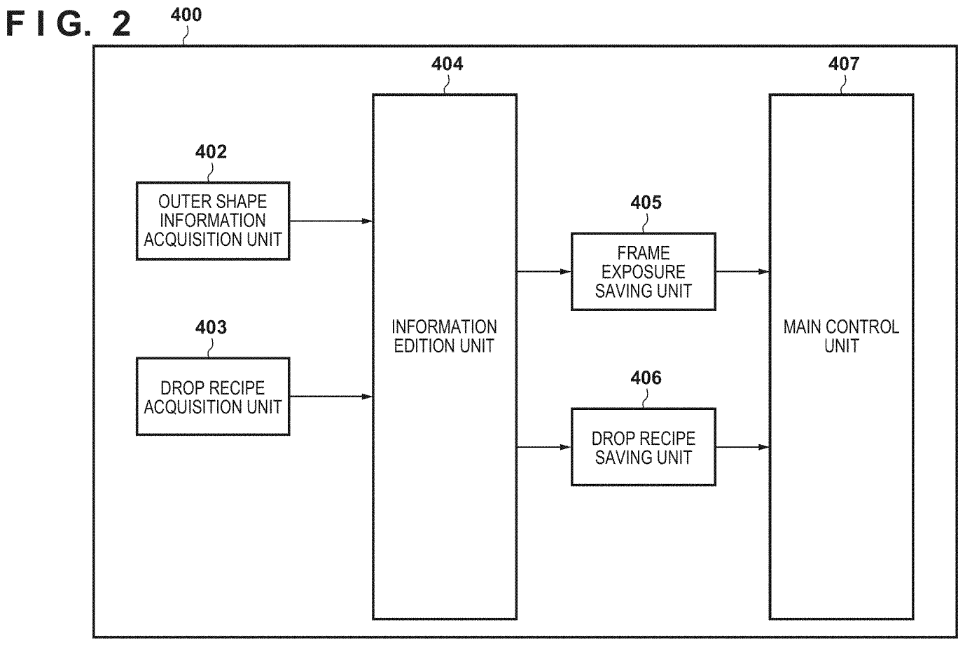

FIG. 2 is a view for explaining an example of processing blocks in the control unit 400. The control unit 400 includes an outer shape information acquisition unit 402, a drop recipe acquisition unit 403, an information edition unit 404, a frame exposure saving unit 405, a drop recipe saving unit 406, and a main control unit 407.

The outer shape information acquisition unit 402 acquires information regarding the shape (outer shape) of a shot region of the substrate 1 and information regarding the shape (outer shape) of the pattern region P of the mold 18, and transmits the information to the information edition unit 404. As described above, examples of the shape of the shot region of the substrate 1 include a rectangular shape and a jigsaw shape. Information regarding the shape of the pattern region P of the mold 18 is generated, for example, by extracting layer data, which influences the unevenness of the pattern, from the design data of the mold 18 and converting it into a visible form.

The drop recipe acquisition unit 403 acquires a drop recipe (supply information) which is information indicating the supply positions and supply amount of the imprint material to be supplied on the substrate, and transmits the drop recipe to the information edition unit 404.

The information edition unit 404 has following functions (1), (2), (3), (4), (5), (6), and (7).
(1) a function of editing (setting) and displaying information included in frame exposure irradiation conditions, more specifically, irradiation region information regarding the irradiation region (distribution) in frame exposure, exposure dose information regarding the light exposure dose (irradiation intensity) in the irradiation region, and time information regarding the start time and end time of the light irradiation
(2) a function of extracting, from the drop recipe, and displaying information regarding the supply positions to which the imprint material is to be supplied on the substrate
(3) a function of displaying information regarding the shape of the shot region of the substrate 1
(4) a function of superimposing, on the coordinate system of the substrate 1, and displaying information regarding the shape of the pattern region P of the mold 18, information regarding the shape of the underlying pattern formed on the substrate 1, or information regarding the result of the imprint processing
(5) a function of selectively displaying the pieces of information displayed by the functions (1), (2), (3), and (4)
(6) a function of transmitting the information included in the frame exposure irradiation conditions to the frame exposure saving unit 405
(7) a function of transmitting the drop recipe to the drop recipe saving unit 406

Note that frame exposure is a process performed before the imprint material is cured by irradiating the entire imprint material with light in a state in which the imprint material on the substrate is in contact with the mold 18. More specifically, frame exposure is a process in which upon bringing the mold 18 into contact with the imprint material on the substrate, the imprint material on the substrate is locally (for example, in a frame shape) irradiated with light in accordance with the irradiation conditions to locally increase the viscosity of the imprint material or locally evaporate the imprint material. With such frame exposure, when the imprint material on the substrate is brought into contact with the mold 18, it is possible to prevent the imprint material from oozing out to the outer peripheral portion of the shot region on the substrate. In this embodiment, the light source unit 11 and the control unit 400 function as a processing unit for performing frame exposure.

The frame exposure saving unit 405 generates frame exposure data indicating the irradiation position and the exposure dose in time series from the information included in the frame exposure irradiation conditions so that the main control unit 407 can easily control the light source unit 11. In addition, the frame exposure saving unit 405 transmits the generated frame exposure data to the main control unit 407. The frame exposure data transmitted to the main control unit 407 is saved in the frame exposure saving unit 405 so that it can be reused.

The drop recipe saving unit 406 generates discharge pattern data indicating the discharge timing of the imprint material in time series from the drop recipe so that the main control unit 407 can easily control the imprint material supply unit 23. In addition, the drop recipe saving unit 406 transmits the generated discharge pattern data to the main control unit 407. The discharge pattern data transmitted to the main control unit 407 is saved in the drop recipe saving unit 406 so that it can be reused.

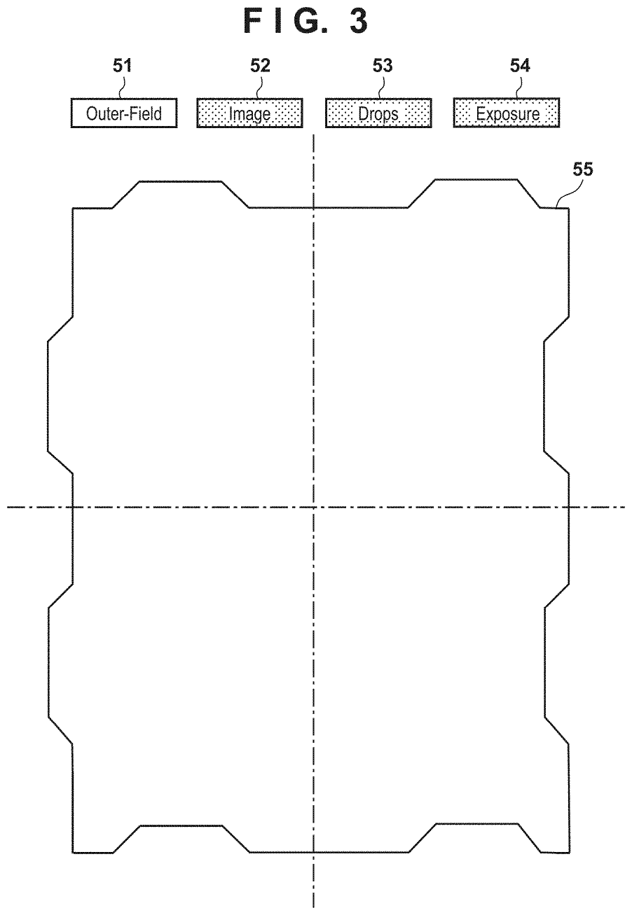

FIG. 3 shows a screen provided (displayed) as the user interface 34 on a display to display and edit (set) imprint conditions. The user interface 34 is provided by the control unit 400. In the user interface 34, it is possible to display a part of the shot region of the substrate 1 enlarged or reduced to an arbitrary magnification by operating a mouse wheel. In FIG. 3, an Outer-Field button 51 is a button for switching display/non-display of a shape 55 of the shot region of the substrate 1. A user can switch display/non-display of the shape 55 of the shot region of the substrate 1 by operating (for example, touching or clicking with a mouse) the Outer-Field button 51. While the shape 55 of the shot region of the substrate 1 is displayed, the Outer-Field button 51 is displayed in, for example, a bright color. On the other hand, while the shape 55 of the shot region of the substrate 1 is not displayed, the Outer-Field button 51 is displayed in, for example, a dark color. FIG. 3 shows a case in which the shape 55 of the shot region of the substrate 1 is a jigsaw shape.

In FIG. 3, an Image button 52 is a button for switching display/non-display of the shape of the pattern region P of the mold 18. A user can switch display/non-display of the shape of the pattern region P of the mold 18 by operating the Image button 52. A Drops button 53 is a button for switching display/non-display of the supply positions to which the imprint material is to be supplied on the substrate. Note that in this embodiment, marks imitating droplets of the imprint material are displayed at the supply positions to which the imprint material is to be supplied. A user can switch display/non-display of the supply positions to which the imprint material is to be supplied by operating the Drops button 53. While the supply positions to which the imprint material is to be supplied are displayed, edition (setting) such as change, addition, or deletion of the supply position can be performed. An Exposure button 54 is a button for switching display/non-display of the frame exposure irradiation conditions (irradiation region information, exposure dose information, time information). A user can switch display/non-display of the frame exposure irradiation conditions by operating the Exposure button 54. While the frame exposure irradiation conditions are displayed, edition (setting) such as change, addition, or deletion of the irradiation condition can be performed. The four buttons of the Outer-Field button 51, the Image button 52, the Drops button 53, and the Exposure button 54 are collectively called display switching buttons hereinafter.

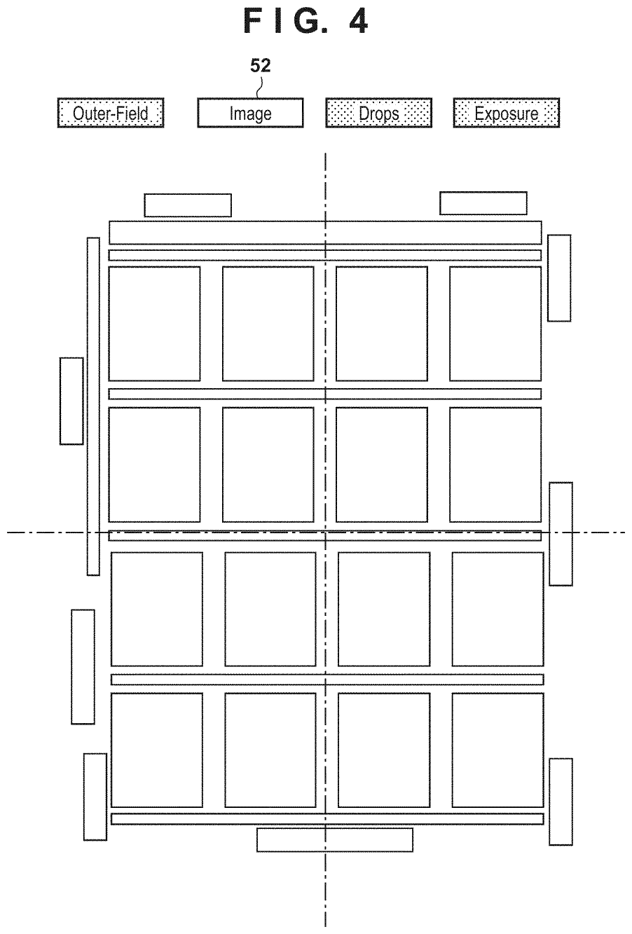

FIG. 4 shows a state in which the Image button 52 is operated and the shape of the pattern region P of the mold 18 is displayed. The display switching buttons other than the Image button 52 are not operated, so that only the Image button 52 is displayed in a bright color and the display switching buttons other than the Image button 52 are displayed in a dark color.

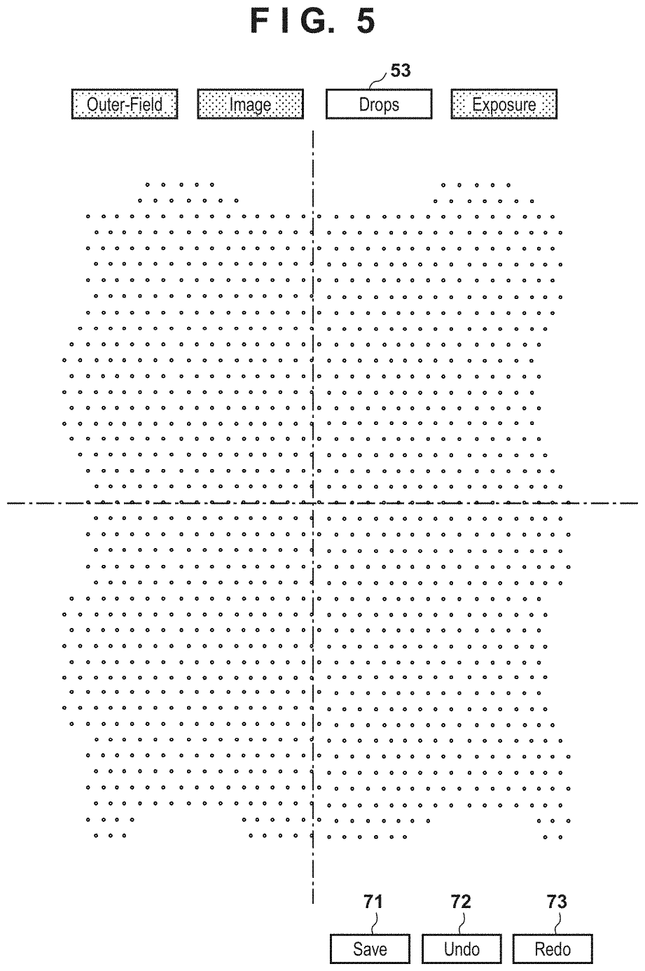

FIG. 5 shows a state in which the Drops button 53 is operated and the supply positions to which the imprint material is to be supplied on the substrate are displayed. More specifically, the marks imitating the imprint material are displayed at the supply positions. The display switching buttons other than the Drops button 53 are not operated, so that only the Drops button 53 is displayed in the bright color and the display switching buttons other than the Drops button 53 are displayed in the dark color. In the state shown in FIG. 5, by selecting (operating) the mark imitating the droplet of the imprint material, it is possible to perform edition such as change or deletion of the imprint material supply position. In addition, it is possible to add a new position as the imprint material supply position by designating the new position. A Save button 71 is a button for designating the name of a file and saving the information edited by the above-described operation therein. An Undo button 72 is a button for returning the information edited by the above-described operation to the previous information. A Redo button 73 is a button for canceling the operation of the Undo button 72.

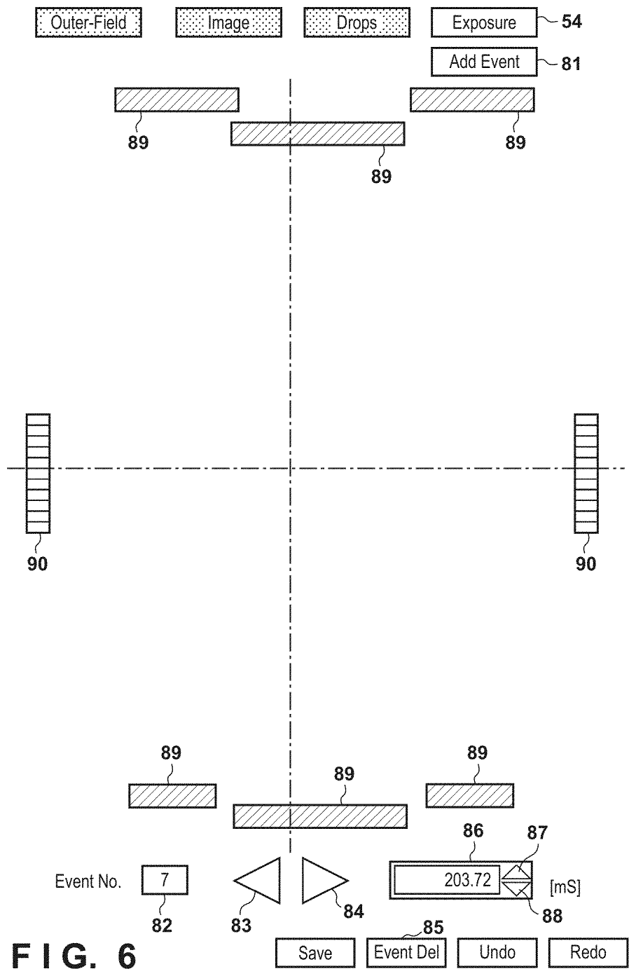

FIG. 6 shows a state in which the Exposure button 54 is operated and the frame exposure irradiation conditions (irradiation region information, exposure dose information, time information) are displayed. The display switching buttons other than the Exposure button 54 are not operated, so that only the Exposure button 54 is displayed in the bright color and the display switching buttons other than the Exposure button 54 are displayed in the dark color.

In FIG. 6, an Add Event button 81 is a button for adding an irradiation pattern event corresponding to each time during the frame exposure. One event is added by operating the Add event button 81 once. An Event No. display field 82 displays the number indicating the event order. An event added by operating the Add Event button 81 is automatically assigned the number indicating the event order in ascending order of event time. A return button 83 is a button for returning the frame exposure irradiation conditions displayed in the user interface 34 to those in the previous event. A feed button 84 is a button for feeding the frame exposure irradiation conditions displayed in the user interface 34 to those in the next event. An Event Del button 85 is a button for deleting the event.

In FIG. 6, an event time setting field 86 is a field for setting the start time and end time (irradiation time), that is, the irradiation timing of light irradiation in the frame exposure as a time in the reference time of the imprint processing. A time increment button 87 is a button for increasing the time set in the event time setting field 86 for each minimum resolution time. A time decrement button 88 is a button for decreasing the time set in the event time setting field 86 for each minimum resolution time. The event time setting field 86 (the time increment button 87 and the time decrement button 88) functions as a setting unit for a user setting the frame exposure irradiation condition via the user interface 34.

Each of irradiation regions 89 and 90 represents an irradiation region to be irradiated with light in the frame exposure. The light exposure dose for the irradiation region 89 is different from the light exposure dose for the irradiation region 90. Therefore, in FIG. 6, the irradiation region 89 is indicated by diagonal lines and the irradiation region 90 is indicated by horizontal lines, thereby distinguishing the light exposure doses for the respective irradiation regions from each other. Note that the light exposure doses for the respective irradiation regions may be distinguished from each other by displaying the irradiation region 89 and the irradiation region 90 in different colors.

The Add Event button 81, the Event No. display field 82, the return button 83, the feed button 84, and the Event Del button 85 are displayed only when the Exposure button 54 has been operated. Similarly, the event time setting field 86, the time increment button 87, and the time decrement button 88 are displayed only when the Exposure button 54 has been operated.

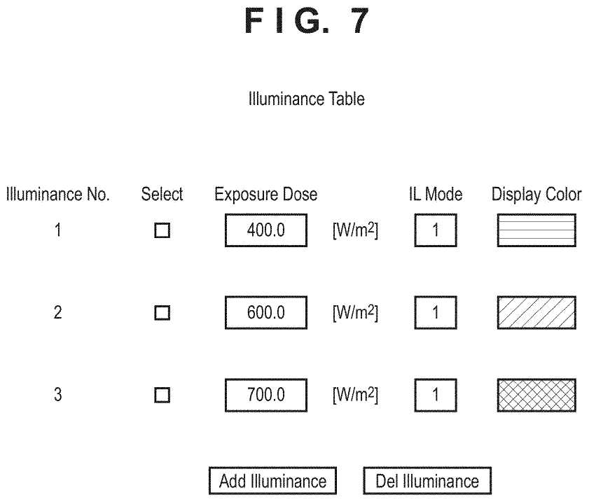

FIG. 7 shows an Illuminance Table (screen) for setting, as the frame exposure irradiation conditions, an irradiation pattern including the exposure dose of the light irradiation in the frame exposure and the irradiation type of the light irradiation in the frame exposure. In this manner, the Illuminance Table serves as a setting unit for a user setting the frame exposure irradiation conditions via the user interface 34. A new irradiation pattern can be added by operating the Add Illuminance button. In the Illuminance No. field, the numbers automatically assigned to a plurality of types of set irradiation patterns are displayed. The Exposure Dose input field is an input field for setting the exposure dose of each irradiation pattern. The IL Mode field is a field for selecting (setting) the irradiation mode. The irradiation mode is set by a combination of an optical slit (not shown) and a specific length transmission filter (not shown) serving as a pre-designated condition, and the property or wavelength of the light source is switched by selecting the number designating the irradiation mode. The Display Color field is a field for setting a color for displaying each irradiation pattern. For example, the irradiation region 89 shown in FIG. 6 is set to Illuminance No. 2, and its Exposure Dose is set to 600.0. Similarly, the irradiation region 90 shown in FIG. 6 is set to Illuminance No. 1, and its Exposure Dose is set to 400.0. The Del Illuminance button is a button for deleting an unnecessary irradiation pattern by checking and operating the Select check box.

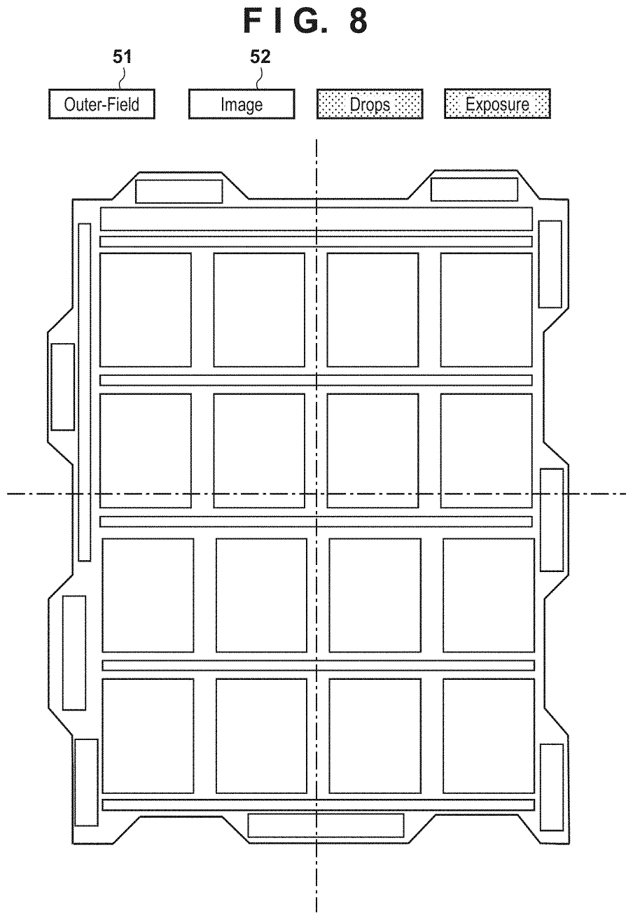

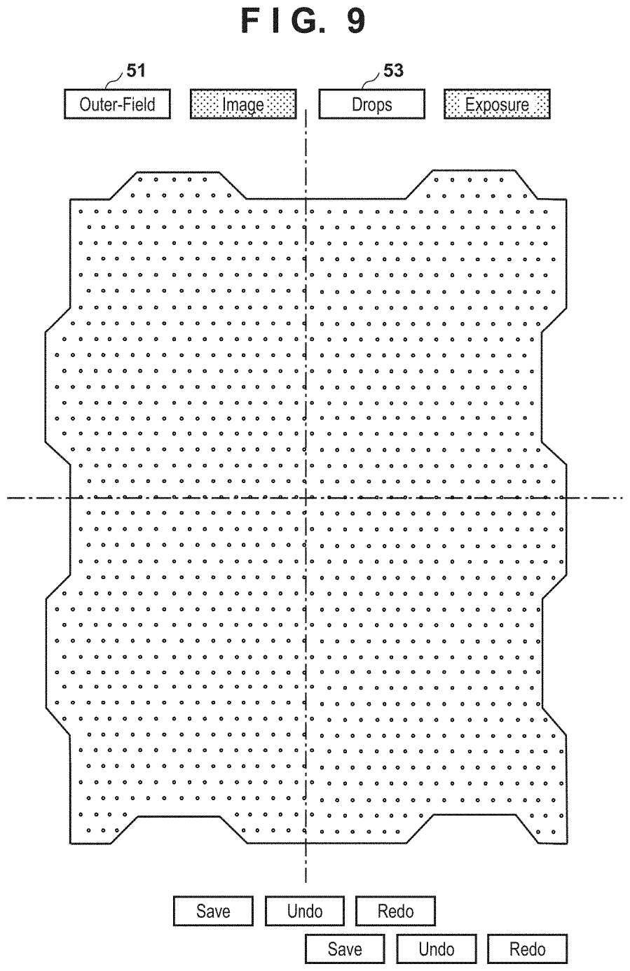

FIG. 8 shows a state in which the Outer-Field button 51 and the Image button 52 are operated so that the shape of the shot region of the substrate 1 and the shape of the pattern region P of the mold 18 are superimposed with each other and displayed simultaneously. FIG. 9 shows a state in which the Outer-Field button 51 and the Drops button 53 are operated so that the shape of the shot region of the substrate 1 and the marks imitating the imprint material at the supply positions to which the imprint material is to be supplied on the substrate are superimposed with each other and displayed simultaneously.

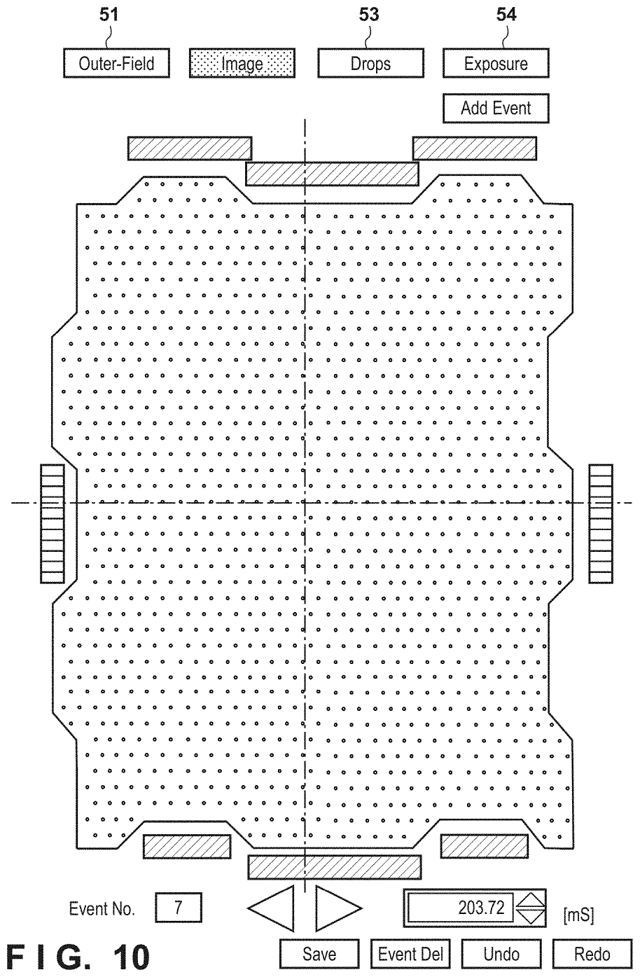

FIG. 10 shows a state in which the Outer-Field button 51, the Drops button 53, and the Exposure button 54 are operated. In this case, the shape of the shot region of the substrate 1, the marks imitating the imprint material at the supply positions to which the imprint material is to be supplied on the substrate, and the frame exposure irradiation conditions are superimposed with each other and displayed simultaneously.

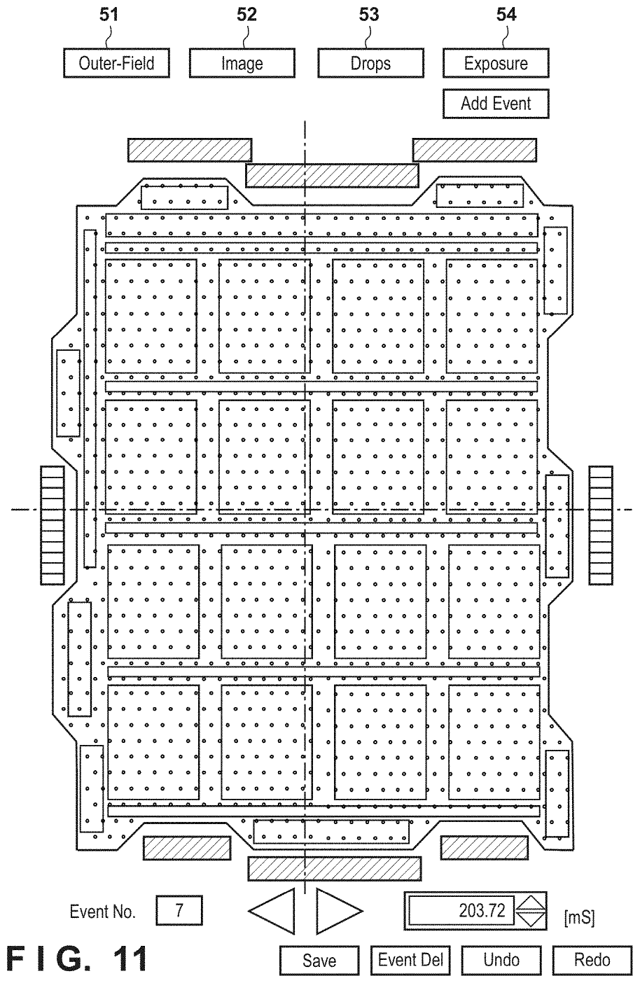

FIG. 11 shows a state in which the Outer-Field button 51, the Image button 52, the Drops button 53, and the Exposure button 54 are operated. In this case, the shape of the shot region of the substrate 1, the shape of the pattern region P of the mold 18, the marks imitating the imprint material at the supply positions to which the imprint material is to be supplied on the substrate, and the frame exposure irradiation conditions are superimposed with each other and displayed simultaneously.

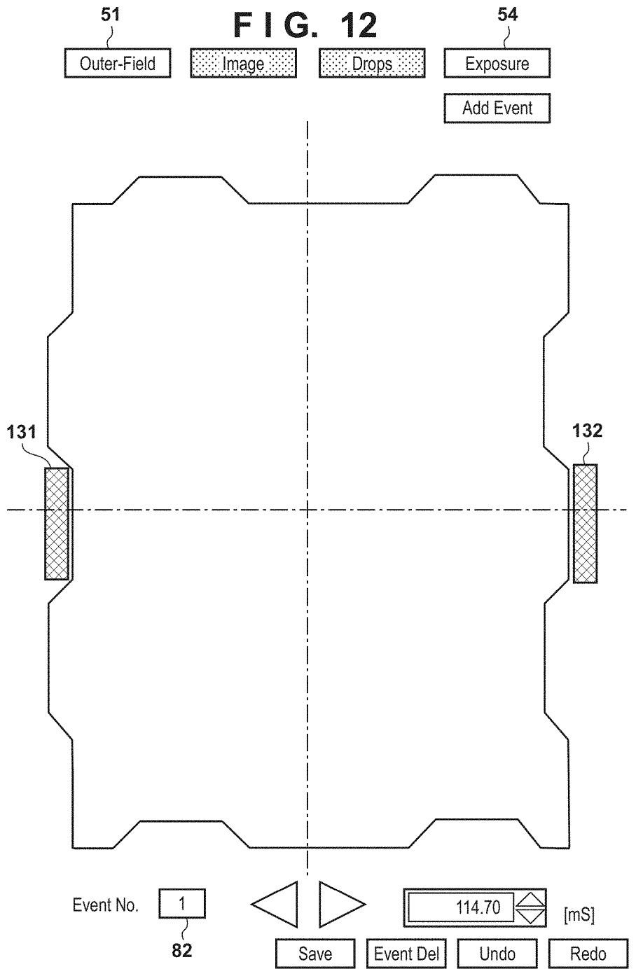

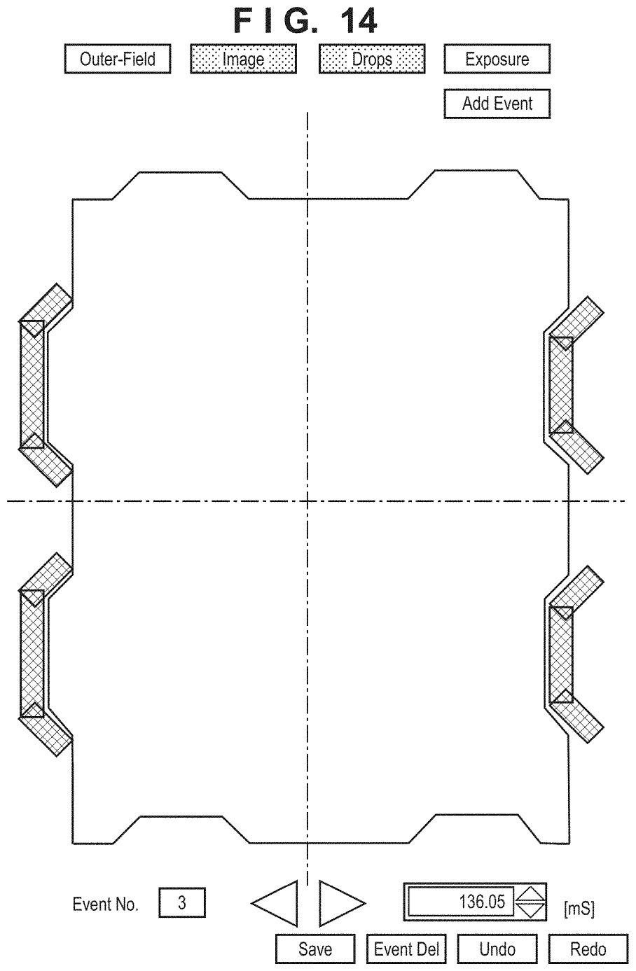

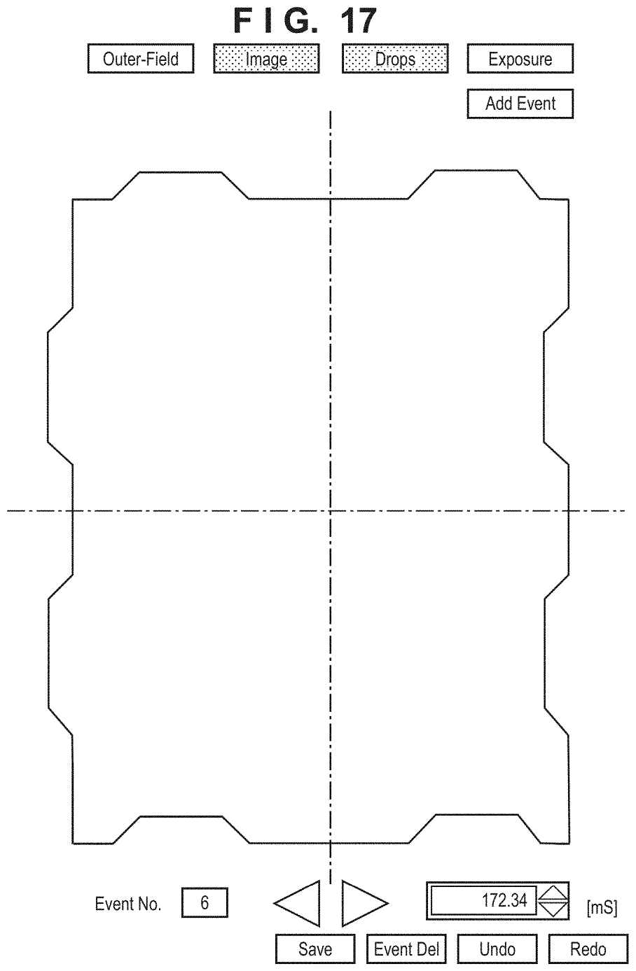

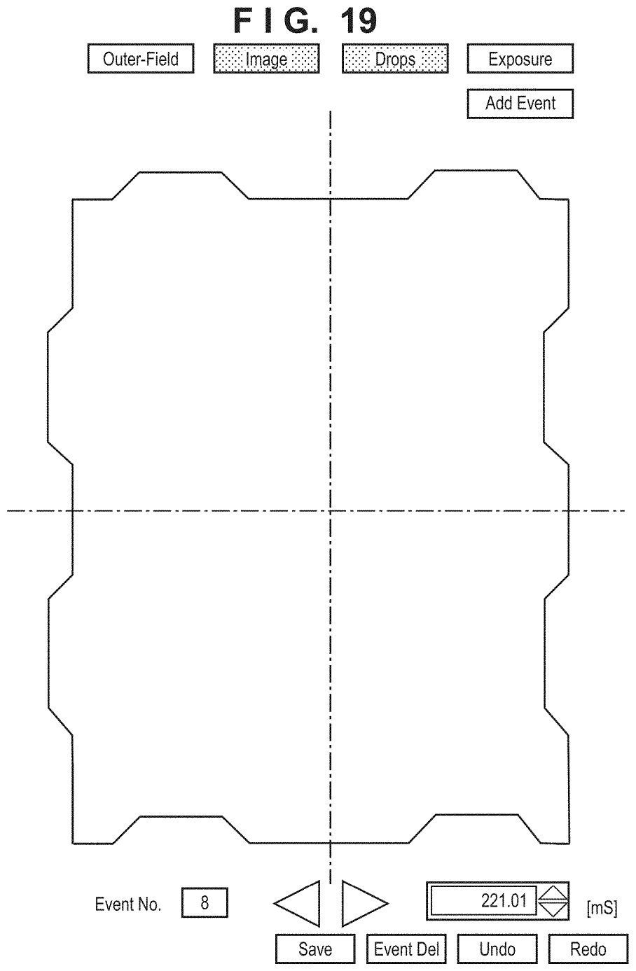

Each of FIGS. 12 to 19 shows a state in which the Outer-Field button 51 and the Exposure button 54 are operated so that the shape of the shot region of the substrate 1 and the frame exposure irradiation conditions are superimposed with each other and displayed simultaneously. FIGS. 12 to 19 show events corresponding to Event Nos. 1 to 8, respectively, as displayed in the Event No. display field 82. In the frame exposure, light irradiation is performed in the irradiation pattern set for each event in the order of the event numbers displayed in the Event No. display field 82.

Note that when editing the irradiation region, its range is set using, for example, a mouse, a touch pen, coordinate input, or the like. The exposure dose is set by selecting the number in the Illuminance No. field in the Illuminance Table shown in FIG. 7. The timing of switching the irradiation pattern is set using the time set in the event time setting field 86.

Referring to FIG. 12, with respect to irradiation regions 131 and 132 located on the left and right of the shot region of the substrate 1, respectively, an exposure dose of 700.0 [W/m²] is set by selecting (setting) “3” in the Illuminance No. field in the Illuminance Table. In addition, referring to the setting in the event time setting field, it can be seen that FIG. 12 shows an event in which the irradiation regions 131 and 132 are irradiated with light from 114.70 [mS] in the reference time of the imprint processing.

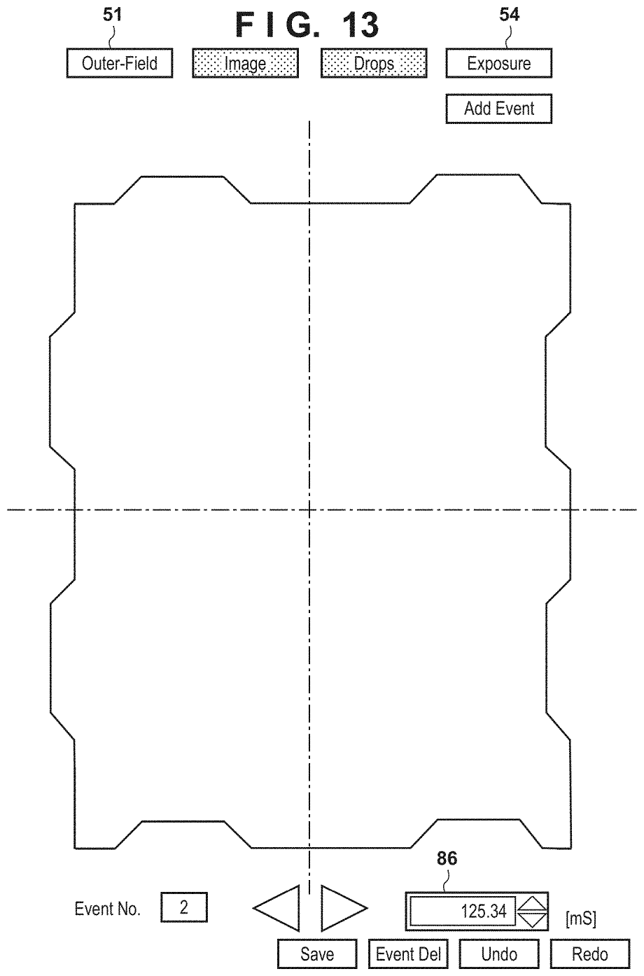

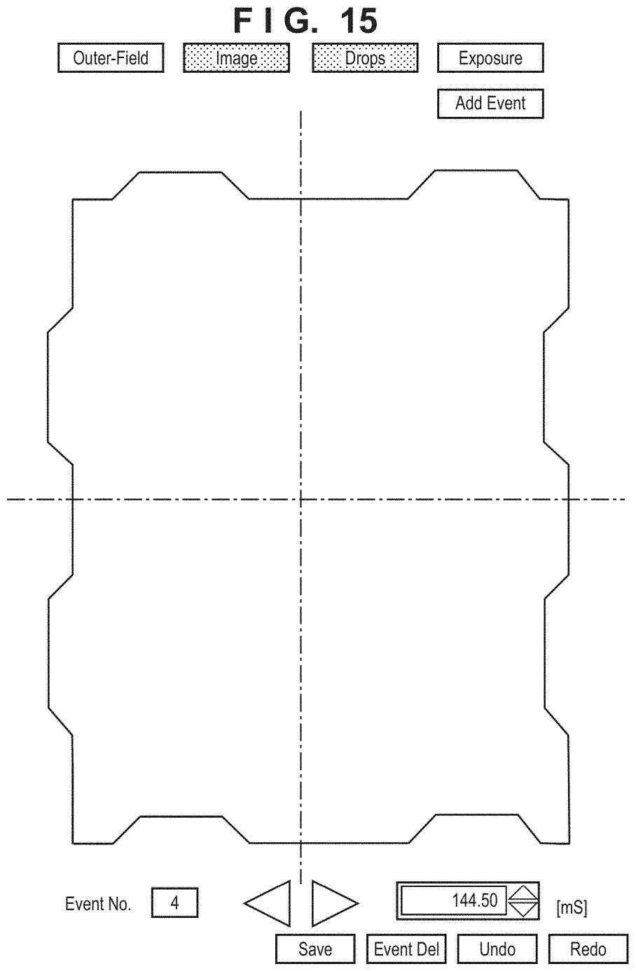

FIG. 13 shows a state in which the Outer-Field button 51 and the Exposure button 54 are operated so that the shape of the shot region of the substrate 1 and the frame exposure irradiation conditions are superimposed with each other and displayed simultaneously. Note that in FIG. 13, an irradiation region to be irradiated with light in the frame exposure is not set. Accordingly, referring to the setting in the event time setting field, it can be seen that FIG. 13 shows an event in which the substrate 1 (shot region) is not irradiated with light from 125.34 [mS] in the reference time of the imprint processing. It can be also seen that each of FIGS. 15, 17, and 19 shows an event in which the substrate 1 is not irradiated with light, as in FIG. 13.

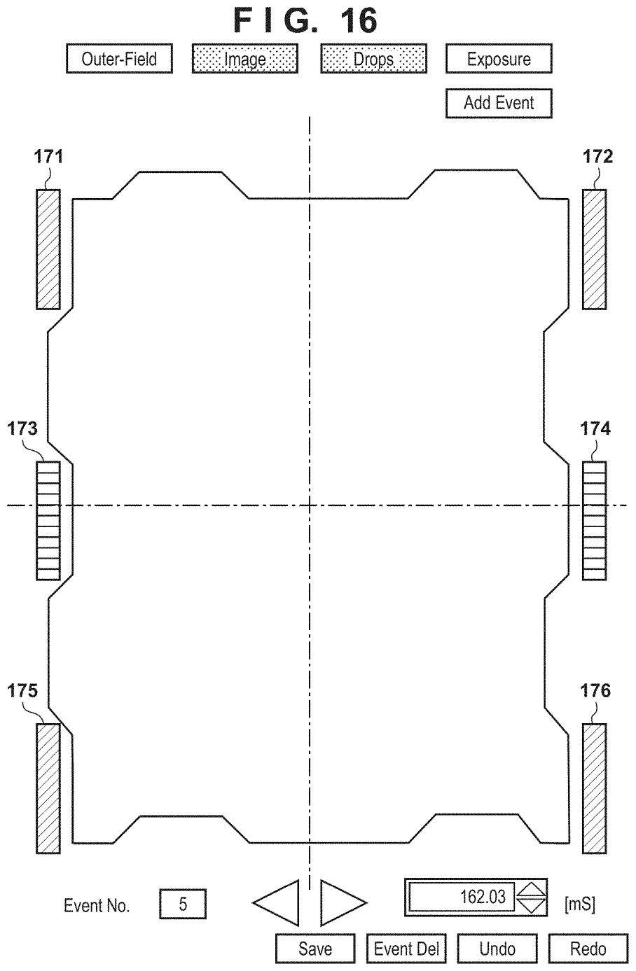

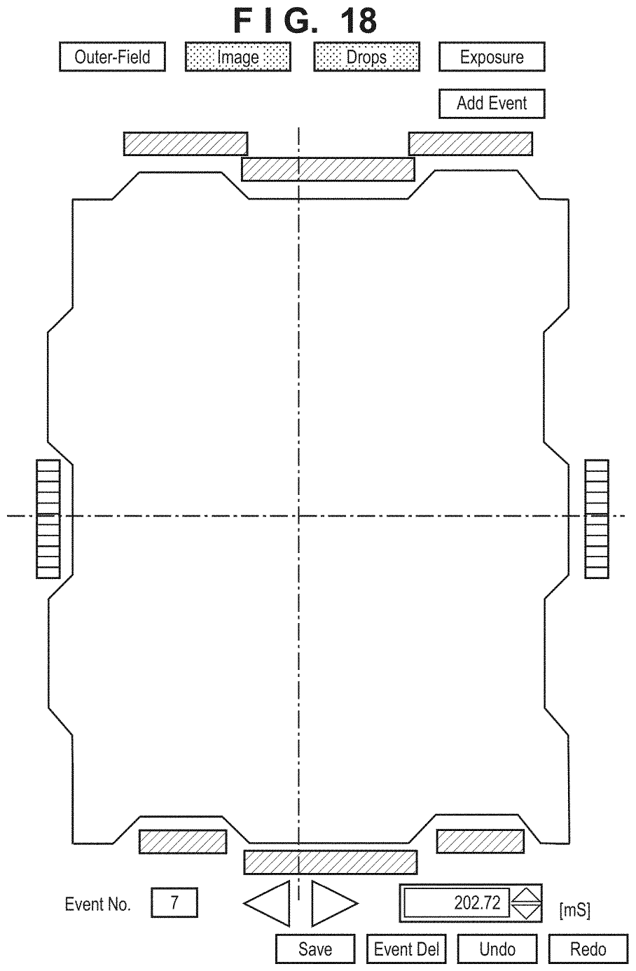

Referring to FIG. 16, in Event No. 5, with respect to irradiation regions 171, 172, 175, and 176, an exposure dose of 600.0 [W/m²] is set by selecting (setting) “2” in the Illuminance No. field in the Illuminance Table. With respect to irradiation regions 173 and 174, an exposure dose of 400.0 [W/m²] is set by selecting “1” in the Illuminance No. field in the Illuminance Table. Referring to the setting in the event time setting field, it can be seen that FIG. 16 shows an event in which the irradiation regions 171 to 176 are irradiated with light from 162.03 [mS] in the reference time of the imprint processing. In this manner, when the different exposure doses are set for the respective irradiation regions, edition (setting) of the irradiation pattern can be facilitated by, for example, changing the color (display method) to display the irradiation region in accordance with the exposure dose. It can be also seen that FIG. 18 shows an event similar to that shown in FIG. 16.

Note that the images corresponding to the respective events shown in FIGS. 12 to 19 may be displayed in the user interface 34 as a moving image. In this case, they are displayed in the user interface 34 such that, for example, the image corresponding to each time is synchronized with the elapsed time from the start of the frame exposure. Further, an input unit for inputting (adjusting) the speed (play speed) to display the images shown in FIGS. 12 to 19 as a moving image may be displayed in the user interface 34, and the images shown in FIGS. 12 to 19 may be displayed at the speed input by a user via the input unit.

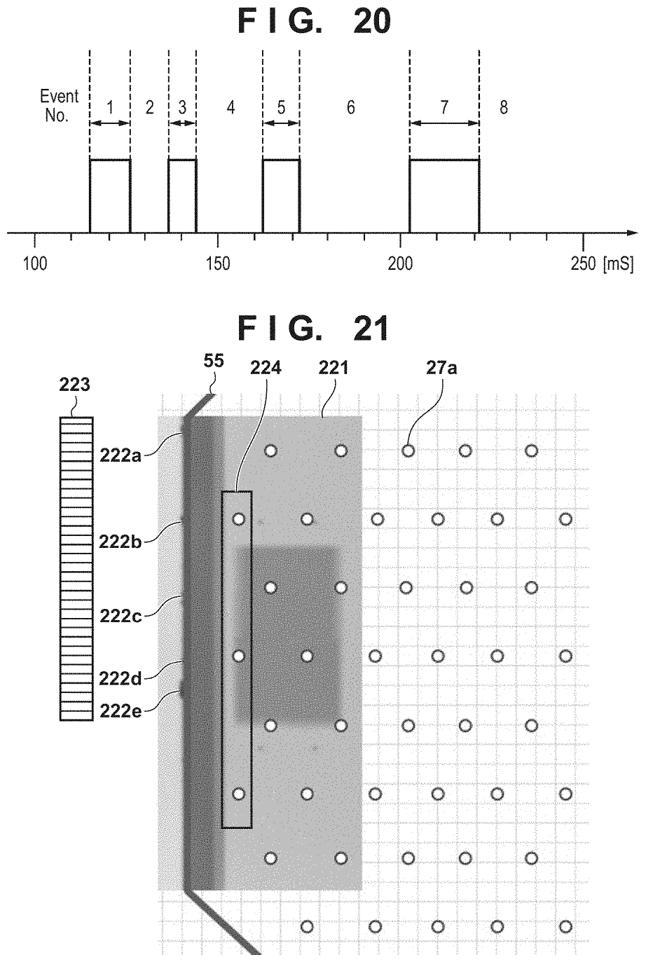

FIG. 20 is a view showing changes in exposure dose of light irradiation in the frame exposure when Event No. transitions from 1 to 8 as the time elapsed in the reference time of the imprint processing. In FIG. 20, the abscissa represents the elapsed time in the reference time of the imprint processing. As shown in FIG. 20, each of Event Nos. 1, 3, 5, and 7 indicates an event in which the set irradiation regions are irradiated with light in the exposure dose set in each Event No. On the other hand, each of Event Nos. 2, 4, 6, and 8 indicates an event in which no light irradiation is performed since no irradiation region and no exposure dose are set in each Event No. Note that since Event No. 8 is the last Event No., the irradiation pattern set in Event No. 8 is maintained until the end of the imprint processing.

In each of FIGS. 4, 8, and 11, the shape of the pattern region P of the mold 18 generated by extracting layer data, which influences the unevenness of the pattern, from the design data of the mold 18 and converting it into a visible form is displayed. However, instead of the shape of the pattern region P of the mold 18 or by superimposing on the shape of the pattern region P of the mold 18, as shown in FIG. 21, information regarding the result of imprint processing, which is an image 221 representing the result of the imprint processing in this embodiment, may be displayed. As the image 221, an image acquired by the detection unit 26 or an image acquired by the off-axis scope 24 may be used. Further, an image representing the result of the imprint processing acquired by an image capturing apparatus (not shown) provided outside the imprint apparatus 200 may be acquired via the network 301 and used as the image 221. The image 221 need not be an image corresponding to the entire shot region of the substrate 1, and an image corresponding to the peripheral region of a specific shot region may be partially displayed in accordance with the coordinate information of the shot region.

FIG. 21 shows a state in which the image 221 representing the result of the imprint processing, the shape 55 of the shot region of the substrate 1, and the supply positions to which the imprint material is to be supplied on the substrate are superimposed with each other and displayed. Referring to the image 221, oozing portions (defects) 222a, 222b, 222c, 222d, and 222e of the imprint material have occurred. The user can check the oozing portions 222a to 222e via the user interface 34 and, for example, select a group 224 of the marks representing the supply positions of the imprint material in the vicinity of the oozing portions to move the supply positions to the right side (in the center direction of the shot region). In addition, the user can set (add), via the user interface 34, a new irradiation region 223 on the left side (in the outward direction of the shot region) in the vicinity of the oozing portions. The image 221 may be a still image or a moving image. The image 221 may be an image that changes depending on the elapsed time. Setting the image 221 as a moving image or an image that changes depending on the elapsed time is advantageous in determining an event (Event No.) in which a new irradiation region is to be set.

The shape of the pattern region P of the mold 18 is often displayed when the frame exposure irradiation conditions and the drop recipe are first determined. In this embodiment, since the above-described screens can be checked via the user interface 34 when setting the frame exposure irradiation conditions and drop recipe with respect to the new mold 18 (the pattern thereof), the efficiency of the setting can be greatly improved. In other words, it is possible to reduce the burden on a user for setting the drop recipe and the frame exposure irradiation conditions, and improve usability by enabling easy setting of the drop recipe and the frame exposure irradiation conditions.

An image representing the result of imprint processing is often displayed in a tuning process in which the imprint processing is performed in practice in accordance with the various types of conditions set via the user interface 34 and the defects in such imprint processing are reduced. Note that instead of the image representing the result of the imprint processing, the underlayer pattern of the substrate 1, that is, an image (third image) representing the unevenness of the substrate 1 may be displayed.

In the imprint apparatus 200, it is required that the pattern of the mold 18 is quickly filled with the imprint material so as to bring the number of unfilled portions close to zero when the imprint material is cured, as well as that the imprint material is prevented from oozing out to the outer peripheral portion of the shot region of the substrate 1. There is a reciprocal relationship between the unfilling of the imprint material in the mold 18 and the oozing of the imprint material. For example, if a large amount of imprint material is supplied to reduce the unfilling, the oozing increases, and if the supply of imprint material is decreased to suppress the oozing, the unfilling increases.

In frame exposure to suppress the oozing, if the irradiation timing is too early compared to the filling, the imprint material supply positions are too close to each other, or the exposure dose is too large, the imprint material is cured before it reaches the outer peripheral portion of the shot region. This leads to the unfilling (defects). Further, if the irradiation timing is too late or the exposure dose is too small, the unfilling can be suppressed but the oozing occurs. Therefore, it can be said that the frame exposure is closely related to the unfilling and the oozing.

In this embodiment, as described above, the image (first image) including the information indicating the frame exposure irradiation conditions and the image (second image) representing at least one of the supply positions of the imprint material and the shape of the pattern region P of the mold 18 are superimposed with each other and displayed in the same shot coordinate system. Thus, the work efficiency can be improved and work errors can be reduced when setting many conflicting conditions, so that the time required for the setting can be shortened. More specifically, the frame exposure irradiation conditions and drop recipe for reducing the unfilling of the imprint material to the pattern of the mold and suppressing the oozing out of the imprint material to the outer peripheral portion of the shot region can be set easily in a short time.

Note that the irradiation region to be irradiated with light in the frame exposure is set outside the shot region in this embodiment, but the irradiation region to be irradiated with light in the frame exposure can be set inside the shot region. Further, the shape of the irradiation region is not necessarily limited to the frame shape, and may be a circular shape or a ring shape. In addition, the full field shot region located in the center of the substrate 1 has been described as an example in this embodiment, but this embodiment is also applicable to a partial field shot region (partial shot region) located in the periphery of the substrate 1.

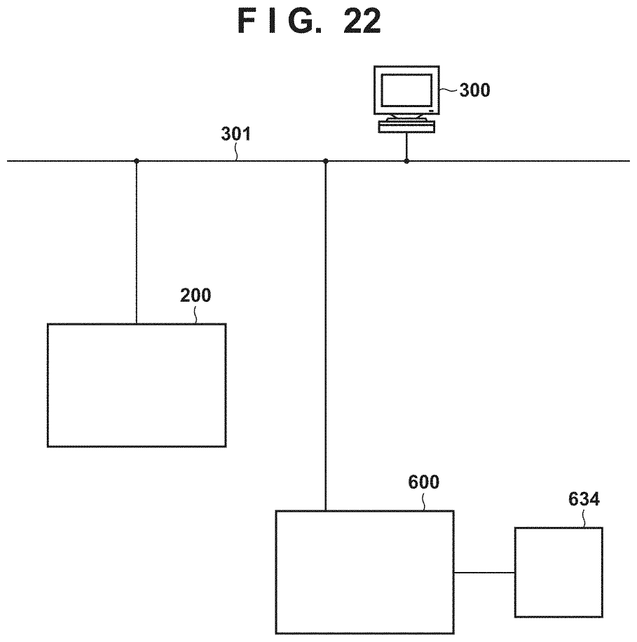

In addition, the functions described in this embodiment can be implemented not in the imprint apparatus 200 (control unit 400) but in an external information processing apparatus (computer) different from the imprint apparatus 200. FIG. 22 is a view showing an example of a system including an information processing apparatus 600 that provides a user interface for setting frame exposure irradiation conditions, the imprint apparatus 200, and the supervising control apparatus 300. The information processing apparatus 600 is utilized by being directly connected to a user interface 634. The information processing apparatus 600 is also connected to the imprint apparatus 200 and the supervising control apparatus 300 via the network 301.

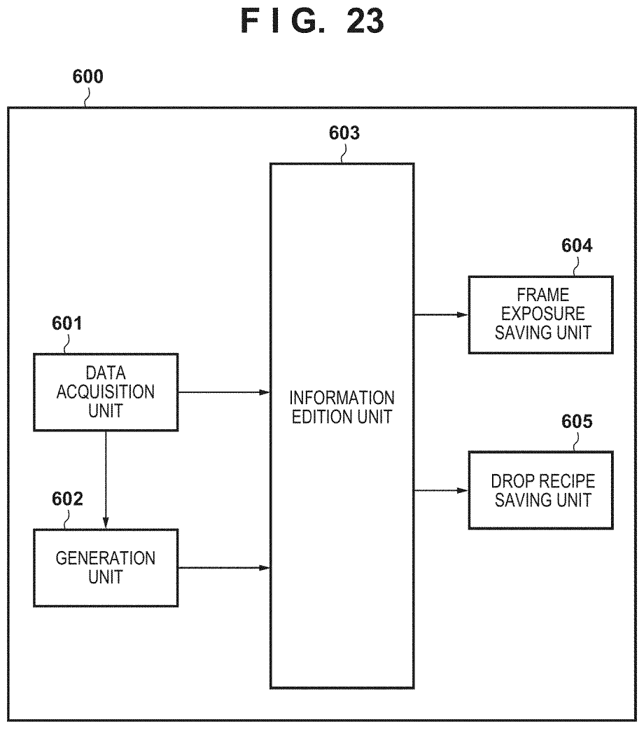

FIG. 23 is a view showing an example of processing blocks in a control unit of the information processing apparatus 600. The control unit includes a data acquisition unit 601, a generation unit 602, an information edition unit 603, a frame exposure saving unit 604, and a drop recipe saving unit 605.

The data acquisition unit 601 acquires following pieces of information (1), (2), (3), and (4).
(1) information regarding imprint conditions including the residual film thickness (RLT) and the volume per drop of the imprint material discharged from the imprint material supply unit 23
(2) the shape (information regarding the outer shape) of the shot region of the substrate 1 and design data of the mold 18
(3) an image representing the result of the imprint processing acquired by the imprint apparatus 200 or an external image capturing apparatus different from the imprint apparatus 200
(4) information regarding the underlying pattern of the substrate 1

The data acquisition unit 601 transmits, to the generation unit 602, the information regarding the imprint conditions, the shape of the shot region of the substrate 1, and the design data of the mold 18. In addition, the data acquisition unit 601 transmits the image representing the result of the imprint processing and the information regarding the underlying pattern of the substrate 1 to the information edition unit 603.

Based on the information from the data acquisition unit 601, more specifically, the information regarding the imprint conditions, the shape of the shot region of the substrate 1, and the design data of the mold 18, the generation unit 602 generates information regarding the shape of the pattern region P of the mold 18 and a drop recipe.

The information edition unit 603, the frame exposure saving unit 604, and the drop recipe saving unit 605 have the functions similar to those of the above-described information edition unit 404, the frame exposure saving unit 405, and the drop recipe saving unit 406, respectively, and the detailed description thereof will be omitted herein. Note that the frame exposure data saved in the frame exposure saving unit 604 and the discharge pattern data saved in the drop recipe saving unit 605 are transmitted to the imprint apparatus 200 via the network 301.

The pattern of a cured product formed using the imprint apparatus 200 is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

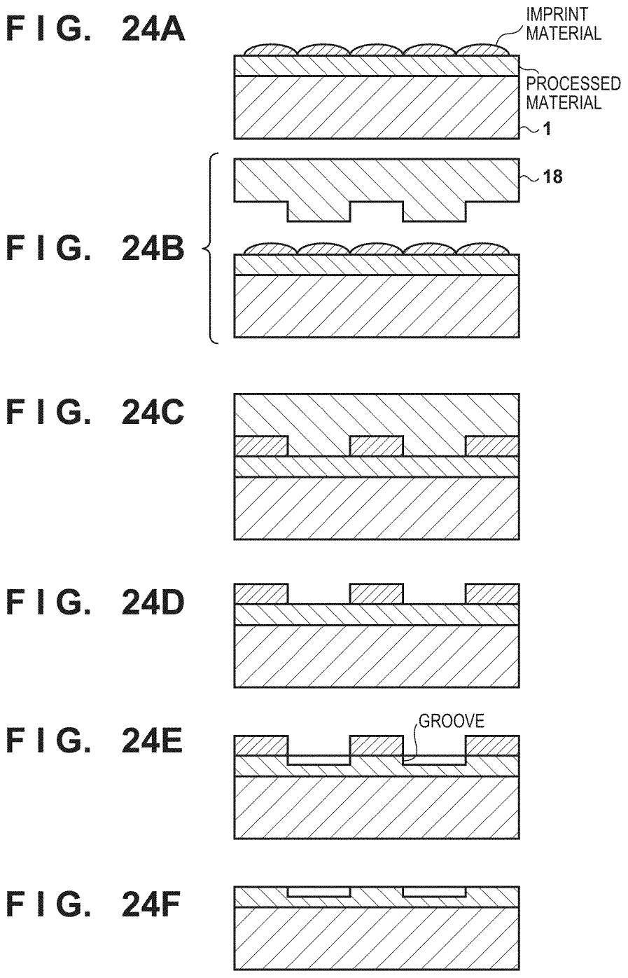

A detailed method of manufacturing an article will be described next. As shown in FIG. 24A, the substrate 1 such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 24B, a side of the mold 18 for imprint with an uneven pattern is directed to and caused to face the imprint material on the substrate. As shown in FIG. 24C, the substrate 1 to which the imprint material is applied is brought into contact with the mold 18, and a pressure is applied. The gap between the mold 18 and the processed material is filled with the imprint material. In this state, when the imprint material is irradiated with light serving as curing energy through the mold 18, the imprint material is cured.

As shown in FIG. 24D, after the imprint material is cured, the mold 18 is separated from the substrate 1. Thus, the pattern of the cured product of the imprint material is formed on the substrate. In the pattern of the cured product, the concave portion of the mold 18 corresponds to the convex portion of the cured product, and the convex portion of the mold 18 corresponds to the concave portion of the cured product. That is, the uneven pattern of the mold 18 is transferred to the imprint material.

As shown in FIG. 24E, when etching is performed using the pattern of the cured product as an etching resistant mask, a portion of the surface of the processed material where the cured product does not exist or remains thin is removed to form a groove. As shown in FIG. 24F, when the pattern of the cured product is removed, an article with the grooves formed in the surface of the processed material can be obtained. Here, the pattern of the cured product is removed. However, instead of processing or removing the pattern of the cured product, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2018-234712 filed on Dec. 14, 2018, which is hereby incorporated by reference herein in its entirety.

What is claimed is:

1. An imprint apparatus that performs imprint processing to form a pattern of an imprint material on a substrate using a mold, comprising:
a processing unit configured to, before the imprint material is cured by irradiating the entire imprint material with light in a state in which the imprint material and a pattern region of the mold are in contact with each other, perform processing of locally irradiating the imprint material on the substrate with light in accordance with an irradiation condition to locally increase a viscosity of the imprint material; and
a control unit configured to provide a user interface in which a first image including information included in the irradiation condition and indicating an irradiation region to be irradiated with light in a region on the substrate and a second image indicating at least one of a supply position to which the imprint material is to be supplied on the substrate and a shape of the pattern region of the mold are superimposed with each other and displayed.

2. The apparatus according to claim 1, wherein the first image includes information included in the irradiation condition and indicating a light exposure dose in the irradiation region.

3. The apparatus according to claim 1, wherein the first image includes information included in the irradiation condition and indicating a light irradiation time in the irradiation region.

4. The apparatus according to claim 1, wherein the control unit superimposes and displays, in the user interface; a third image including at least one of information indicating a result of the imprint processing and information indicating unevenness of the substrate on the first image and the second image.

5. The apparatus according to claim 1, wherein
the irradiation region changes for each time during performing the processing, and
the control unit displays, as a moving image, the first images corresponding to the respective times superimposed on the second image in the user interface.

6. The apparatus according to claim 5, wherein the control unit superimposes and displays, in the user interface, the first images corresponding to the respective times on the second image such that the first image corresponding to each time is synchronized with an elapsed time from a start of the processing.

7. The apparatus according to claim 5, wherein the control unit displays, in the user interface, an input unit configured to allow a user to input, via the user interface, a speed to display the first images as a moving image.

8. The apparatus according to claim 1, wherein the control unit displays, in the user interface, a setting unit configured to allow a user to set the irradiation condition via the user interface.

9. An information processing apparatus that provides a user interface for setting an irradiation condition upon performing, in an imprint apparatus that performs imprint processing to form a pattern of an imprint material on a substrate using a mold, before the imprint material is cured by irradiating the entire imprint material with light in a state in which the imprint material and a pattern region of the mold are in contact with each other, processing of locally irradiating the imprint material on the substrate with light to locally increase a viscosity of the imprint material, comprising
a control unit configured to provide the user interface in which a first image including information included in the irradiation condition and indicating an irradiation region to be irradiated with light in a region on the substrate and a second image indicating at least one of a supply position to which the imprint material is to be supplied on the substrate and a shape of the pattern region of the mold are superimposed with each other and displayed,
wherein the control unit displays, in the user interface, a setting unit configured to allow a user to set the irradiation condition via the user interface.

10. A method of manufacturing an article, comprising:
forming a pattern on a substrate using an imprint apparatus defined in claim 1;
processing the substrate on which the pattern is formed in the forming; and
manufacturing the article from the processed substrate.
